(19) United States
(12) Patent Application Publication
(10) Pub. No.: US 2024/0258195 A1
(43) Pub. Date: Aug. 1, 2024

(54) BONDED BODY COMPRISING MOSAIC DIAMOND WAFER AND SEMICONDUCTOR OF DIFFERENT TYPE, METHOD FOR PRODUCING SAME, AND MOSAIC DIAMOND WAFER FOR USE IN BONDED BODY WITH SEMICONDUCTOR OF DIFFERENT TYPE

(71) Applicants: NATIONAL INSTITUTE OF ADVANCED INDUSTRIAL SCIENCE AND TECHNOLOGY, Tokyo (JP); MITSUBISHI ELECTRIC CORPORATION, Tokyo (JP)

(72) Inventors: Hideaki YAMADA, Osaka (JP); Akiyoshi CHAYAHARA, Osaka (JP); Yoshiaki MOKUNO, Osaka (JP); Takashi MATSUMAE, Saitama-shi (JP); Yuuichi KURASHIMA, Tsukuba-shi (JP); Eiji HIGURASHI, Tsukuba-shi (JP); Hideki TAKAGI, Tsukuba-shi (JP); Shuichi HIZA, Tokyo (JP); Ken IMAMURA, Tokyo (JP); Yusuke SHIRAYANAGI, Tokyo (JP); Koji YOSHITSUGU, Tokyo (JP); Kunihiko NISHIMURA, Tokyo (JP)

(21) Appl. No.: 18/565,295

(22) PCT Filed: May 31, 2022
(86) PCT No.: PCT/JP2022/022138

§ 371 Date: Nov. 29, 2023

(30) Foreign Application Priority Data
May 31, 2021 (JP) 2021-091708

(51) Int. Cl. H01L 23/373; B32B 9/00; B32B 9/04; B32B 37/18; B32B 38/00; C30B 29/04; C30B 29/40; C30B 33/00; H01L 23/00

(52) U.S. Cl. CPC H01L 23/3732; B32B 9/007; B32B 9/04; B32B 37/18; C30B 29/04; C30B 29/406; C30B 33/00; H01L 24/32; H01L 24/83; B32B 2038/0064; B32B 2457/14; H01L 2224/32225; H01L 2224/83005

(57) ABSTRACT

This bonded body (10) comprising a mosaic diamond wafer and a semiconductor of a different type is a bonded body in which a mosaic diamond wafer (1) having a coalescence boundary (B1) between a plurality of single-crystal diamond substrates (1A and 1B) and a semiconductor of a different type (2) are bonded together, in which a maximum level difference on a bonding surface (1aa) of the mosaic diamond wafer (1) with the semiconductor of a different type (2) is 10 nm or less.

### TECHNICAL FIELD

The present disclosure relates to a bonded body comprising a mosaic diamond wafer and a semiconductor of a different type, a method for producing the same, and a mosaic diamond wafer for use in a bonded body with a semiconductor of a different type.

Priority is claimed on Japanese Patent Application No. 2021-091708, filed May 31, 2021, the content of which is incorporated herein by reference.

### BACKGROUND ART

For power devices such as GaN devices, there is a need of cooling, but no sufficient cooling methods have been yet developed. In such a situation, studies are underway to use diamond materials having a high thermal conductivity as heat dissipation base materials.

Patent Literature 1 describes a wafer having a polycrystalline diamond layer grown or bonded on GaN.

Non Patent Literature 1 discloses a GaN-high electron mobility transistor (HEMT) in which a single-crystal diamond substrate is used as a heat dissipation substrate.

### CITATION LIST

### Patent Literature

### Patent Literature 1

Japanese Unexamined Patent Application Publication No. 2015-533774

### Patent Literature 2

Japanese Patent No. 4849691

### Non Patent Literature

### Non Patent Literature 1

S. Hiza, M. Fujikawa, Y. Takiguchi, K. Nishimura, E. Yagyu, T. Matsumae, Y. Kurashima, H. Takagi, and M. Yamamuka: Extended Abstracts of the 2019 International Conference on Solid State Devices and Materials, 467 (2019).

### Non Patent Literature 2

Meguro, Nishibayashi, and Imai, SEI Technical Review 163, 53 (2003)

### SUMMARY OF INVENTION

### Technical Problem

Ordinarily, polycrystalline diamond has a lower thermal conductivity than single-crystal diamond due to the presence of grain boundaries. In a case where a thermal conductivity as high as that of single-crystal diamond is required, there is a need to devise growth conditions, but the growth rate remains at 1/10 or slower of that of a single crystal. In addition, mechanical polishing or the like is required for the flattening of grown surfaces, but the polishing rate of diamond is significantly anisotropic, and thus the polishing rate becomes significantly slow in the case of polycrystalline diamond compared with a single crystal. For the above-described reasons, in a case where polycrystalline diamond is intended to be used as a bonded wafer, it is considered that the production cost becomes extremely high compared with that for single-crystal diamond. Furthermore, in the case of polycrystals, due to the orientations of crystal grains or the presence of a particle size distribution that is attributed to the unevenness of the growth atmosphere or the like, warpage or the like is likely to occur, and reduction thereof is technically difficult. In addition, due to the above-described anisotropy, it is difficult to obtain a surface suitable for wafer bonding by mechanical polishing. As a result, a thick interlayer is required to bond a GaN wafer and a polycrystalline wafer, which creates a problem in that the interlayer acts as a thermal barrier to significantly degrade the heat dissipation effect of devices.

On the other hand, a single-crystal diamond substrate can be, substantially, directly bonded with a GaN wafer through an extremely thin interlayer (<5 nm), but there are no inch-sized single-crystal diamond wafers, and thus there is a problem in that wafer-level bonding is not possible and the cost becomes high.

The present disclosure has been made in consideration of the above-described circumstances, and an object of the present disclosure is to provide a bonded body comprising a mosaic diamond wafer and a semiconductor of a different type that has high heat dissipation characteristics and can be made larger, a method for producing the same, and a mosaic diamond wafer for use in a bonded body with a semiconductor of a different type.

### Solution to Problem

A mosaic diamond wafer is a mosaic-like diamond wafer obtained by bonding a plurality of single-crystal diamond substrates arranged on the same surface by growing diamond crystals by a gas-phase method thereon to make a large diamond single-crystal wafer (for example, refer to Non Patent Literature 2).

FIG. 9 shows an optical microscopic image of the vicinity of a coalescence boundary of a typical mosaic diamond wafer obtained by the method described in Patent Literature 2. In FIG. 9, a part indicated by arrows is the coalescence boundary between single-crystal diamond substrates.

In the mosaic diamond wafer, for example, even in a case where a plurality of single-crystal diamond substrates are disposed in a crystal growth apparatus such that the crystal orientations thereof are aligned, it is likely that a coalescence boundary abnormally grow (polycrystallize) and the crystal orientations become anisotropic. In FIG. 9, it is found that the coalescence boundary is significantly different from other portions, which reflects abnormal growth (polycrystallization).

FIG. 10 shows a cathodoluminescence mapping image of the vicinity of the coalescence boundary of the mosaic diamond wafer. The length of one side of the cathodoluminescence mapping image is 125 μm.

In the cathodoluminescence mapping image, crystal defects are present in regions where no light is emitted (non-luminescent centers). It is found that, in the cathodoluminescence mapping image, non-luminescent centers with a complex structure concentrate in the vicinity of the coalescence boundary.

It is relatively easy to increase the area of the mosaic diamond wafer compared with single-crystal diamond while the mosaic diamond wafer has similar qualities to single-crystal diamond. Therefore, if it is possible to use the mosaic diamond wafer as a heat dissipation base material, the above-described problem of the single-crystal diamond substrate can be solved. However, coalescence boundaries between the single-crystal diamond substrates that configure the mosaic diamond wafer correspond to grain boundaries in polycrystalline diamond, and thus persons skilled in the art consider that, similar to polycrystalline diamond, the mosaic diamond wafer cannot be directly bonded with a GaN wafer. Additionally, since there is another problem peculiar to the mosaic diamond wafer, that is, defects or distortions concentrating in the coalescence boundary as shown in FIG. 9 and FIG. 10, persons skilled in the art could not even imagine that the mosaic diamond wafer can be directly bonded with a GaN wafer.

As a result of intensive studies, the present inventors realized direct bonding of a mosaic diamond wafer and a GaN wafer and completed the present disclosure.

The present disclosure provides the following means to solve the above-described problems.

A bonded body comprising a mosaic diamond wafer and a semiconductor of a different type according to a first aspect of the present disclosure is a bonded body in which the mosaic diamond wafer having a coalescence boundary between a plurality of single-crystal diamond substrates and the semiconductor of a different type are bonded together, in which a maximum level difference on a bonding surface of the mosaic diamond wafer with the semiconductor of a different type is 10 nm or less.

In the bonded body comprising a mosaic diamond wafer and a semiconductor of a different type according to the above-described aspect, the semiconductor of a different type may be one selected from the group consisting of gallium nitride, gallium oxide, silicon and silicon carbide.

In the bonded body comprising a mosaic diamond wafer and a semiconductor of a different type according to the above-described aspect, the mosaic diamond wafer and the semiconductor of a different type may be directly bonded with each other.

In the bonded body comprising a mosaic diamond wafer and a semiconductor of a different type according to the above-described aspect, the mosaic diamond wafer and the semiconductor of a different type may be bonded with each other through an interlayer.

A method for producing a bonded body comprising a mosaic diamond wafer and a semiconductor of a different type according to a second aspect of the present disclosure has a step of selecting a mosaic diamond wafer which has a coalescence boundary between a plurality of single-crystal diamond substrates and in which a maximum level difference on a bonding surface of the mosaic diamond wafer with the semiconductor of a different type is 10 nm or less.

A method for producing a bonded body comprising a mosaic diamond wafer and a semiconductor of a different type according to a third aspect of the present disclosure has a step of preparing a mosaic diamond wafer having a coalescence boundary between a plurality of single-crystal diamond substrates and a step of polishing a surface of the mosaic diamond wafer until a maximum level difference in the coalescence boundary becomes 10 nm or less.

The method for producing a bonded body comprising a mosaic diamond wafer and a semiconductor of a different type according to the above-described aspect has a step of fabricating an epitaxial substrate having a layer of a semiconductor of a different type epitaxially grown on a main surface of a growth substrate, a step of attaching the epitaxial substrate onto a support substrate through an adhesive layer, a step of removing the growth substrate to expose the layer of the semiconductor of a different type, a step of bonding the layer of the semiconductor of a different type and a polished surface of the mosaic diamond wafer, and a step of removing the adhesive layer to obtain a bonded body comprising the mosaic diamond wafer and the semiconductor of a different type.

A mosaic diamond wafer for use in a bonded body comprising a mosaic diamond wafer and a semiconductor of a different type according to a fourth aspect of the present disclosure is a mosaic diamond wafer that is used in a bonded body in which a mosaic diamond wafer having a coalescence boundary between a plurality of single-crystal diamond substrates and a semiconductor of a different type are bonded together, in which a maximum level difference on a bonding surface of the mosaic diamond wafer with the semiconductor of a different type is 10 nm or less.

### Advantageous Effects of Invention

According to the bonded body comprising a mosaic diamond wafer and a semiconductor of a different type according to the present disclosure, it is possible to provide a bonded body comprising a mosaic diamond wafer and a semiconductor of a different type that has high heat dissipation characteristics and can be made larger.

### BRIEF DESCRIPTION OF DRAWINGS

FIG. 1 is a schematic cross-sectional view conceptually showing the configuration of a bonded body comprising a mosaic diamond wafer and a semiconductor of a different type according to one embodiment of the present disclosure.

FIG. 2 is a schematic perspective view conceptually showing a method for fabricating a mosaic diamond wafer, FIG. 2(a) is a schematic perspective view of a first step, FIG. 2(b) is a schematic perspective view of a second step, and FIG. 2(c) is a schematic perspective view of a third step.

FIG. 3 is a schematic cross-sectional view showing the outline of the configuration of a polishing device that is used to polish the mosaic diamond wafer.

FIG. 4 is a schematic cross-sectional view for describing each step regarding one example of a method for producing a bonded body comprising a mosaic diamond wafer and a semiconductor of a different type.

FIG. 5 is a schematic cross-sectional view for describing each step regarding one example of the method for producing a bonded body comprising a mosaic diamond wafer and a semiconductor of a different type.

FIG. 6 is a schematic cross-sectional view for describing each step regarding one example of the method for producing a bonded body comprising a mosaic diamond wafer and a semiconductor of a different type.

FIG. 7 is a schematic cross-sectional view for describing each step regarding one example of the method for producing a bonded body comprising a mosaic diamond wafer and a semiconductor of a different type.

FIG. 8(a) is a scanning white-light interference microscopic image of the vicinity of a coalescence boundary in a mosaic diamond wafer used in an example, and FIG. 8(b) is a scanning white-light interference microscopic image of the vicinity of a coalescence boundary in a mosaic diamond wafer used in a comparative example.

FIG. 9 is an optical microscopic image of the vicinity of a coalescence boundary in a mosaic diamond wafer.

FIG. 10 is a cathodoluminescence mapping image of the vicinity of the coalescence boundary in the mosaic diamond wafer.

### DESCRIPTION OF EMBODIMENTS

Hereinafter, a bonded body comprising a mosaic diamond wafer and a semiconductor of a different type, a method for producing the same, and a mosaic diamond wafer for use in a bonded body with a semiconductor of a different type according to the present disclosure will be described using drawings. The drawings are schematic, the correlations of the size and the position between images that are individually shown in different drawings are not always shown accurately, and the relationships and rates of dimensions in the length direction, the depth direction and the height direction are different from the real ones. In addition, in the following description, the same configuration elements will be shown in the drawings with the same reference sign, and the names and functions thereof are also considered to be the same. Therefore, there will be cases where those are not described in detail. In addition, materials, dimensions and the like to be exemplified in the following description are simply examples, and the present disclosure is not limited thereto and can be carried out after being appropriately modified to an extent that the effect of the present disclosure is exhibited. It is also possible to apply a configuration described in one embodiment to other embodiments.

### (Bonded Body Comprising Mosaic Diamond Wafer and Semiconductor of Different Type)

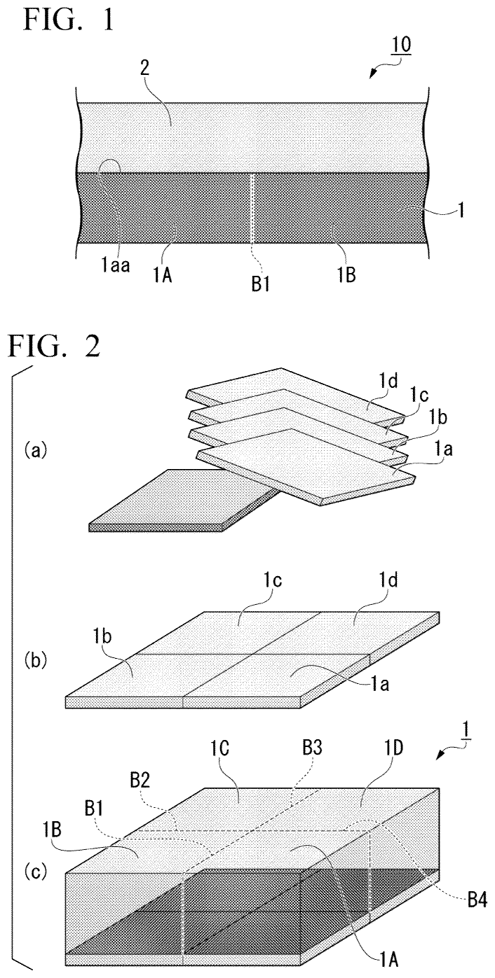

FIG. 1 is a schematic cross-sectional view conceptually showing the configuration of a bonded body comprising a mosaic diamond wafer and a semiconductor of a different type according to one embodiment of the present disclosure.

A bonded body 10 comprising a mosaic diamond wafer and a semiconductor of a different type shown in FIG. 1 is a bonded body in which a mosaic diamond wafer 1 having a coalescence boundary B1 between a plurality of single-crystal diamond substrates 1A and 1B and a semiconductor of a different type 2 are bonded together, in which the maximum level difference on a bonding surface 1aa of the mosaic diamond wafer 1 with the semiconductor of a different type 2 is 10 nm or less.

### <Mosaic Diamond Wafer>

Herein, in the bonded body of the present disclosure, the mosaic diamond wafer is, as described above, a mosaic-like diamond wafer that has been made into a large diamond single-crystal wafer by bonding a plurality of single-crystal diamond substrates arranged on the same surface by growing diamond crystals by a gas-phase method thereon.

### <Method for Fabricating Mosaic Diamond Wafer>

The mosaic diamond wafer can be fabricated as described below.

A plurality of single-crystal diamond substrates are prepared and disposed in a crystal growth apparatus such that the crystal orientations thereof are aligned, and diamond crystals are grown thereon. The crystal growth conditions are not particularly limited as long as a method and conditions allow diamond crystal growth. For example, in the case of using microwave plasma CVD, it is preferable to maintain the temperature of the substrate at approximately 800° C. to 1200° C. with the microwave power set to 5 kW, the raw material gas pressure set to 16 kPa and the flow rate ratio between hydrogen and methane that configure the raw material gas set to approximately 10:0.1 to 1. The installed single-crystal diamond substrates are integrated together by the crystal-grown layer, whereby a mosaic diamond wafer is obtained.

Normally, in the method for fabricating the mosaic diamond wafer, the threshold value at which the off angles of the single-crystal diamond substrates that are intended to be bonded together are regarded as the same is set to a minimum of 1° or more. However, when the off angles are different from each other even by 1°, the quality of the grown layer becomes different under the same conditions, and, on the mosaic diamond wafer bonded by this method, a single-crystal layer having a different quality grows in each of the bonded single-crystal regions. In conventional mosaic diamond wafers, abnormal growth occurred along a coalescence boundary, which was difficult to suppress.

As a method for producing a mosaic diamond wafer intended to solve such a problem, a method using a free-standing membrane fabrication method in which ion implantation is used is known (for example, refer to Patent Literature 2). The use of such a method makes it possible to bonded substrates in which the off angles or the off directions are aligned.

This fabrication method will be described with reference to FIG. 2. In this fabrication method, the mosaic diamond wafer can be fabricated by the following steps;
(1) a step of implanting ions into a parent substrate made of single-crystal diamond (hereinafter, referred to as “single-crystal diamond parent substrate” or simply “parent substrate” in some cases) to form a graphitized non-diamond layer in the vicinity of the surface of the parent substrate and etching the non-diamond layer to separate a single-crystal diamond layer that is a layer above the non-diamond layer (hereinafter, referred to as “single-crystal diamond child substrate” or simply “child substrate” in some cases),
(2) a step of repeating the operation of the step (1) on the parent substrate used in the step (1) to further separate a plurality of single-crystal diamond layers (child substrates) 1a, 1g, 1c and 1d (refer to FIG. 2(a)),
(3) a step of placing the plurality of single-crystal diamond layers separated in the step (1) and the step (2) on a flat supporting table in a state where the side surfaces thereof are in contact with each other, the directions of the crystal planes match and the surfaces separated from the parent substrate are in contact with the surface of the supporting table (refer to FIG. 2(b)), and
(4) a step of growing single-crystal diamond by a gas-phase synthesis method on the plurality of single-crystal diamond layers (child substrates) 1a, 1g, 1c and 1d placed on the supporting table in the step (3) to coalesce the plurality of single-crystal diamond layers (child substrates) 1a, 1g, 1c and 1d, thereby obtaining the mosaic diamond wafer 1 made up of parts 1A, 1B, 1C and 1D derived from the individual child substrates, which are integrated through coalescence boundaries B1, B2, B3 and B4 (refer to FIG. 2(c)).
Furthermore, (5) a step of turning over the single-crystal diamond layers bonded in the step (4) on the supporting table and then growing single-crystal diamond by the gas-phase synthesis method to grow single-crystal diamond on the surfaces separated from the parent substrate may also be performed.

In this fabrication method, the individual child substrates that configure the mosaic diamond wafer 1 are obtained from the same single-crystal diamond parent substrate and thus all have the same crystallographic properties as the parent substrate, and the individual child substrates have the same crystallographic properties. In other words, having the same crystallographic properties refers to the fact that the directions of the crystal planes, such as the off angles or the off directions, or strain, the distributions of defects and the like are aligned. Therefore, there is no need to change the growth conditions of diamond for each child substrate, and the same treatment layers are obtained with respect to the set conditions. Therefore, on this surface, single-crystal diamond can be easily and precisely grown by the gas-phase synthesis method, and thus the properties of a large-area substrate made of the single-crystal diamond that is fabricated by bonding these child substrates are also homogeneous.

The child substrates have the same crystallographic properties are not limited to child substrates obtained by the method as described in Patent Literature 2, and a plurality of single-crystal diamond substrates having the same crystallographic properties may be selected from commercially available single-crystal diamond substrates or single-crystal diamond substrates having the same crystallographic properties may be produced by appropriately adopting a well-known diamond-producing method.

The fact that, in the coalescence boundary of the mosaic diamond wafer, there are many portions where the crystal directions are oriented in the same direction is a decisively different point from polycrystalline diamond.

In contrast, polycrystalline diamond is in a state where portions in which the crystal directions are oriented in different directions on the surface gather together and thus direct bonding with a GaN wafer is considered to be difficult.

### <Method for Polishing Mosaic Diamond Wafer>

As a method for polishing the mosaic diamond wafer, it is possible to use an arbitrary polishing method enabling the flattening of the diamond surface. Examples of well-known polishing method include the Scaife polishing method in which polishing is performed by rubbing diamond particles embedded in a metal surface plate and workpiece diamond, a method in which a thermochemical reaction occurring between a quartz surface plate and diamond is used, a method in which an etching action by oxygen plasma and chemical mechanical polishing are combined together, a polishing method in which an active radical that is generated by a catalytic reaction between a transition metal and hydrogen peroxide is used and the like. These polishing method may be singly used or a plurality of methods may be combined together.

In the polishing step of the mosaic diamond wafer surface, polishing is performed until the maximum level difference on the surface becomes 10 nm or less. Here, “the maximum level difference” on the surface is the maximum value of local height differences in surface shapes measured with a white-light interference microscope at places including at least each coalescence boundary (for example, each coalescence boundary indicated by the reference sign B1, B2, B3 or B4 in FIG. 2). This is because, only in a case where a mosaic diamond wafer having a maximum level difference of 10 nm or less on the bonding surface is used, a bonded body in which the mosaic diamond wafer and a semiconductor of a different type are directly bonded together can be obtained. When the surface roughness indicated by Ra is approximately 10 nm, the surface is extremely rough as a polished surface, and direct bonding with a semiconductor of a different type is not possible. In order for direct bonding with a semiconductor of a different type, the level difference needs to be 10 nm or less in the coalescence boundary, which is a joint between the single-crystal diamond child substrates.

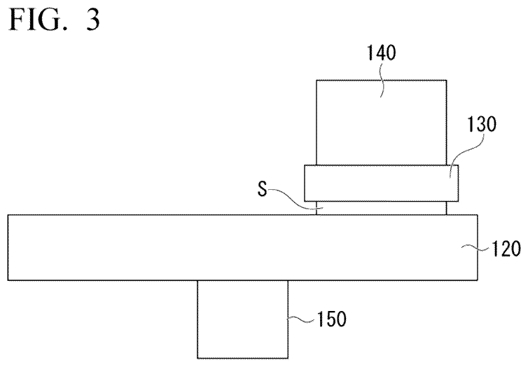

Regardless of a polishing method to be used, a polishing device includes a polishing surface plate 120 mechanically bonded to a rotation mechanism, a sample-holding plate 130 that holds a sample S (mosaic diamond wafer) on the polishing surface plate 120, a pressurization member 140 that imparts a certain load to the sample S and a substrate rotation mechanism 150 that rotates the sample S while pressurizing the sample S through the sample-holding plate 130 to be pressed against the polishing surface plate 120 as schematically shown in FIG. 3. In addition, there are also cases where a member that supplies or holds a chemical liquid such as a polishing agent to the polishing plate surface or the periphery of the workpiece as necessary and a mechanism that heats the plate surface of the surface plate are provided.

In the case of using the Scaife polishing method in which polishing is performed by rubbing diamond particles embedded in a metal surface plate and workpiece diamond, for example, a polishing surface plate having diamond fine particles embedded on a surface plate made of cast iron is used as the polishing surface plate 120. The diamond fine particles are desirably fixed onto the polishing surface plate after being dispersed in a processing oil or the like in advance. In addition, the individual particles are desirably fixed so as to be disposed in an approximately uniform height or density in order to perform high-quality polishing.

In the case of using diamond polishing using the method in which a thermochemical reaction is used, a polishing surface plate made of synthetic quartz can be used as the polishing surface plate 120. In the present method, since the thermochemical reaction occurring between diamond and a quartz surface plate is the essence of the processing principle, a mechanism that heats the polishing plate surface is desirably provided for the purpose of improving the reaction rate.

In the case of using a method in which an etching action by oxygen plasma and chemical mechanical polishing are combined together, a plurality of plasma generation electrodes including an oxygen gas supply path and a polishing plate surface having a path that supplies a chemically active species generated by the plasma generation parts to the processing surface therein are desirably used to enable the uniform supply of an active radical that is generated in the oxygen plasma to the polishing surface. In addition, a polishing pad made of urethane, a nonwoven fabric material or the like is desirably provided on the plate surface. Furthermore, a polishing chemical solution supply device for adding a polishing chemical solution dropwise onto the plate surface at a certain rate is desirably provided.

In the case of using the polishing method in which an active radical that is generated by a catalytic reaction between a transition metal and hydrogen peroxide is used, a metal surface plate made of a transition metal element is used as the polishing surface plate 120. As the surface plate material, for example, iron, nickel or the like can be used. In addition, it is desirable that a chemical solution tank is provided in the periphery of the surface plate 120, an oxidizing agent solution is held in the chemical solution tank and the polishing surface plate 120 is in a state of being immersed in the oxidizing agent solution. Alternatively, the polishing device may have a structure in which not the chemical solution tank but an oxidizing agent solution supply device that adds an oxidizing agent solution dropwise onto the polishing plate surface at a certain rate is provided. As these oxidizing agent solution, for example, a hydrogen peroxide solution diluted to approximately 0.5 to 10 weight percent can be used.

As the conditions, such as the number of rotations of the surface plate and the polishing pressure, of the diamond polishing by each of these methods, arbitrary conditions can be used as long as the maximum level difference on the mosaic diamond wafer surface can be sufficiently reduced.

### (Method for Producing Bonded Body Comprising Mosaic Diamond Wafer and Semiconductor of Different Type)

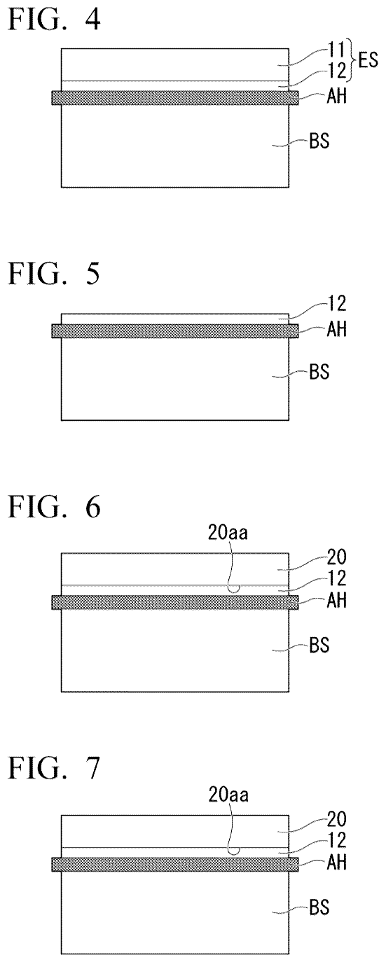

Hereinafter, regarding a method for producing a bonded body comprising a mosaic diamond wafer and a semiconductor of a different type, a case where the semiconductor of a different type is GaN will be described as an example using FIG. 4 to FIG. 7.

First, an epitaxial substrate ES having a GaN layer 12 formed by heteroepitaxial growth on a main surface of a growth substrate 11 such as a Si substrate as shown in FIG. 4 is prepared. On the GaN layer 12, an electron element such as a diode, a transistor or a resistor may be formed in advance. After that, a support substrate BS that is selected from a glass substrate, a sapphire substrate, a Si substrate, a SiC substrate and the like is prepared, and the epitaxial substrate ES and the support substrate BS are pasted together with an adhesive or the like such that a main surface of the epitaxial substrate ES on which the GaN layer 12 is formed and a main surface for pasting (first main surface) of the support substrate BS face each other, thereby producing a form in which the epitaxial substrate ES and the support substrate BS are made to adhere together with an adhesive layer AH.

As the adhesive layer AH, it is possible to use a well-known adhesive material such as a resin adhesive such as an acrylic resin, an epoxy resin, a silicone resin, a modified silicone resin or an alumina adhesive or an inorganic adhesive containing water glass, alumina or the like as a main component, but a non-solvent-diluted resin-based adhesive, which cures by a chemical reaction, is preferably used from the viewpoint of suppressing substrate warpage after the adhesion and ensuring the final removal workability, and, for example, an acrylic resin, an epoxy resin, a silicone resin and the like are suitable.

After the pasting, a curing treatment is performed for the purpose of improving the mechanical strength of the adhesive layer AH. As the curing conditions, arbitrary conditions can be used depending on the adhesive layer AH to be used, and, for example, a heating treatment is performed for six hours in a blower drying oven at 70 degrees.

Since the role of the support substrate BS is to support the GaN layer 12 in the subsequent steps, the support substrate is not limited to the above-described substrates, and arbitrary materials can be used as long as the materials withstand the steps from the viewpoint of heat resistance, mechanical strength and resistance to chemical solutions that are used in the production steps.

Next, the growth substrate 11 is removed as shown in FIG. 5. As a method for removing the growth substrate 11, the growth substrate can be removed from a main surface (rear surface) opposite to the main surface on which the GaN layer 12 is formed using, for example, mechanical polishing, dry etching, wet etching with a solution or the like, but mechanical polishing is suitably used from the viewpoint of the removal rate.

Next, a surface (rear surface) of the GaN layer 12 from which the growth substrate 11 has been removed is polished and flattened. As a flattening method, a well-known method such as mechanical polishing, chemical mechanical polishing (CMP), dry etching or wet etching with a solution can be used, but a chemical mechanical polishing method is suitably used since a high flattening quality is required in order to improve the bonding quality in the subsequent bonding step.

Next, a mosaic diamond wafer 20 made to have a maximum level difference of 10 nm or less on a bonding surface 20aa is pasted to the rear surface of the GaN layer 12 as shown in FIG. 6.

As a method for directly pasting the mosaic diamond wafer 20 to the GaN layer 12, an arbitrary method for directly bonding materials of different types can be used; however, in order to improve the performance and reliability of a nitride semiconductor element, it is desirable to reduce the interfacial thermal resistance between the GaN layer 12 and the mosaic diamond wafer 20 as much as possible. In addition, in order to prevent the warpage of the substrates after bonding, the GaN layer 12 and the mosaic diamond wafer 20 are desirably bonded together without being heated. Therefore, it is most suitable to paste the GaN layer and the mosaic diamond wafer together using a room temperature bonding method. One example of the room temperature bonding method is surface activated room temperature bonding, which is a method in which bonding surfaces are bonded together with atoms on the surfaces put into an active state where chemical bonding is easy by surface-treating the bonding surfaces in a vacuum.

As the room temperature bonding method, it is also possible to use atomic diffusion bonding or hydrophilic group pressure bonding. The atomic diffusion bonding is a method in which metal films are formed on the surfaces of bonding objects by sputtering or the like and the metal films are brought into contact with each other and bonded together in a vacuum.

The hydrophilic group pressure bonding is a method in which a hydrophilization treatment for attaching a large number of hydroxyl groups to the surface of bonding objects is performed and then the hydrophilized surfaces are overlapped, pressurized and bonded together.

In the end, as shown in FIG. 7, the support substrate BS and the adhesive layer AH on the opposite side to the mosaic diamond wafer 20 are removed to obtain a bonded body 30 in which the GaN is formed on the mosaic diamond wafer 20.

A method for removing the support substrate is determined depending on the material of the adhesive layer AH. For example, it is possible to use well-known methods such as a method in which the adhesive layer AH is mechanically torn off from the mosaic diamond wafer 20 together with the support substrate BS, a method in which the adhesive layer AH is immersed in a solvent to embrittle the physical properties and then mechanically torn off from the mosaic diamond wafer 20, a method in which the adhesive layer AH is combusted by a thermal treatment, thereby removing the support substrate BS and a method in which the adhesive layer AH is combusted by a sulfuric acid/hydrogen peroxide mixture treatment, thereby removing the support substrate BS.

Hitherto, the case where the semiconductor of a different type is GaN has been described as an example, but the semiconductor of a different type may be one selected from the group consisting of gallium oxide, silicon and silicon carbide.

In addition, the case where the mosaic diamond wafer and the GaN wafer are directly bonded together has been described, but the mosaic diamond wafer and the GaN wafer may be bonded together through an interlayer.

As the interlayer, a layer made of a material selected from the group of amorphous silicon, amorphous carbon, germanium, a metal and an oxide thereof can be used.

### EXAMPLES

### Example

### <Preparation of Mosaic Diamond Wafer>

A mosaic diamond wafer was fabricated by a method shown in FIG. 2. A sample of the mosaic diamond wafer used this time is four 10 mm×10 mm child substrates bonded together, and the crystal plane of the main surface is a (100) plane.

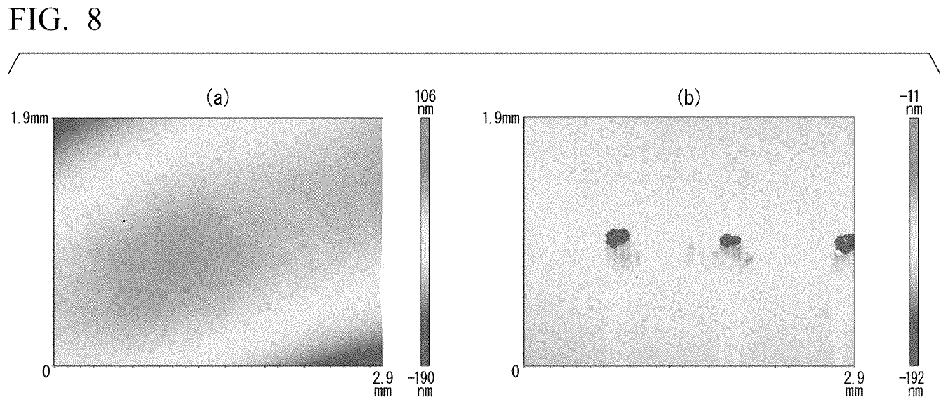

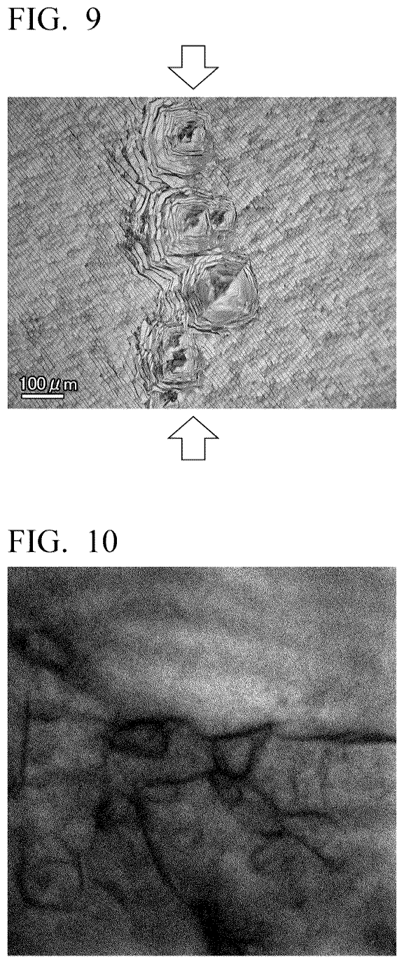

FIG. 8(a) shows a scanning white-light interference microscopic image of the vicinity of a coalescence boundary in the sample of the mosaic diamond wafer after polishing. No level differences or projections and recesses were observed.

Next, a method shown in FIG. 4 to FIG. 7 made it possible to directly bond the mosaic diamond wafer and a GaN wafer by a surface activated room temperature bonding method, and a bonded body comprising the mosaic diamond wafer and the GaN wafer was obtained.

### Comparative Example

Fabrication of a bonded body comprising a mosaic diamond wafer and a GaN wafer was attempted by the same method as in the example except that a sample of the mosaic diamond wafer was fabricated by bonding child substrates obtained from different parent substrates, but bonding was not possible.

FIG. 8(b) shows a scanning white-light interference microscopic image of the vicinity of a coalescence boundary in the sample of the mosaic diamond wafer after polishing. Level differences and projections and recesses were observed in the coalescence boundary, and the maximum level difference was 50 nm or more.

Based on the interference microscopic images of FIG. 8(a) and FIG. 8(b), it is considered that a difference in the flatness of the bonding surface of the mosaic diamond wafer decides the success or failure of the direct bonding between the mosaic diamond wafer and the GaN wafer.

### REFERENCE SIGNS LIST

1, 20 Mosaic diamond wafer
1a, 1b, 1c, 1d Single-crystal diamond child substrate
1aa, 20aa Bonding surface
2 Semiconductor of different type
10, 30 Bonded body comprising mosaic diamond wafer and semiconductor of different type
12 GaN layer (GaN wafer)

1. A bonded body comprising a mosaic diamond wafer and a semiconductor of a different type in which the mosaic diamond wafer having a coalescence boundary between a plurality of single-crystal diamond substrates and the semiconductor of a different type are bonded together,
wherein a maximum level difference on a bonding surface of the mosaic diamond wafer with the semiconductor of a different type is 10 nm or less.

2. The bonded body comprising a mosaic diamond wafer and a semiconductor of a different type according to claim 1,
wherein the semiconductor of a different type is one selected from the group consisting of gallium nitride, gallium oxide, silicon and silicon carbide.

3. The bonded body comprising a mosaic diamond wafer and a semiconductor of a different type according to claim 1,
wherein the mosaic diamond wafer and the semiconductor of a different type are directly bonded with each other.

4. The bonded body comprising a mosaic diamond wafer and a semiconductor of a different type according to claim 1,
wherein the mosaic diamond wafer and the semiconductor of a different type are bonded with each other through an interlayer.

5. A method for producing a bonded body comprising a mosaic diamond wafer having a coalescence boundary between a plurality of single-crystal diamond substrates and a semiconductor of a different type, the method comprising:
a step of selecting a mosaic diamond wafer which has a coalescence boundary between a plurality of single-crystal diamond substrates and in which a maximum level difference on a bonding surface of the mosaic diamond wafer with the semiconductor of a different type is 10 nm or less.

6. A method for producing a bonded body comprising a mosaic diamond wafer and a semiconductor of a different type, the method comprising:
a step of preparing a mosaic diamond wafer having a coalescence boundary between a plurality of single-crystal diamond substrates; and
a step of polishing a surface of the mosaic diamond wafer until a maximum level difference in the coalescence boundary becomes 10 nm or less.

7. The method for producing a bonded body comprising a mosaic diamond wafer and a semiconductor of a different type according to claim 5, the method comprising:
a step of fabricating an epitaxial substrate having a layer of a semiconductor of a different type epitaxially grown on a main surface of a growth substrate;
a step of attaching the epitaxial substrate on a support substrate through an adhesive layer;
a step of removing the growth substrate to expose the layer of the semiconductor of a different type;
a step of bonding the layer of the semiconductor of a different type and a polished surface of the mosaic diamond wafer; and
a step of removing the adhesive layer to obtain a bonded body comprising the mosaic diamond wafer and the semiconductor of a different type.

8. (canceled)

9. The bonded body comprising a mosaic diamond wafer and a semiconductor of a different type according to claim 2,
wherein the mosaic diamond wafer and the semiconductor of a different type are directly bonded with each other.

10. The bonded body comprising a mosaic diamond wafer and a semiconductor of a different type according to claim 2,
wherein the mosaic diamond wafer and the semiconductor of a different type are bonded with each other through an interlayer.

11. The method for producing a bonded body comprising a mosaic diamond wafer and a semiconductor of a different type according to claim 6, the method comprising:
a step of fabricating an epitaxial substrate having a layer of a semiconductor of a different type epitaxially grown on a main surface of a growth substrate;
a step of attaching the epitaxial substrate on a support substrate through an adhesive layer;
a step of removing the growth substrate to expose the layer of the semiconductor of a different type;
a step of bonding the layer of the semiconductor of a different type and a polished surface of the mosaic diamond wafer; and
a step of removing the adhesive layer to obtain a bonded body comprising the mosaic diamond wafer and the semiconductor of a different type.
